(19) United States
(12) Patent Application Publication
(10) Pub. No.: US 2019/0155271 A1
(43) Pub. Date: May 23, 2019

(54) DETERMINING A CHANGE IN ASSET PERFORMANCE USING A DIGITAL TWIN

(71) Applicant: General Electric Company, Schenectady, NY (US)

(72) Inventors: David MATTHEWS, Niskayuna, NY (US); Joel MARKHAM, Niskayuna, NY (US); Michael YOENSKY, Charlottesville, VA (US); Amy Victoria ARAGONES, Niskayuna, NY (US); Austars Raymond SCHNORE, JR., Scotia, NY (US)

(21) Appl. No.: 15/820,730

(22) Filed: Nov. 22, 2017

(51) Int. Cl. G05B 23/02; G01R 21/133

(52) U.S. Cl. CPC G05B 23/0283; G06F 8/61; G01R 21/1331

(57) ABSTRACT

The example embodiments are directed to a system and method for determining an improvement to an asset created by installation of a software application associated with the asset. In one example, the method includes determining an operating performance of an asset operating based on a performance modifying application being installed, establishing a baseline operating performance of the asset from a virtual model of the asset which is running without the performance modifying application installed, determining a change in an operating characteristic of the asset in response to the performance modifying application being installed based on the operating performance of the asset determined from the asset and the baseline operating performance of the asset determined from the virtual model of the asset, and outputting information about the determined change in the operating characteristic of the asset for display on a display device.

### BACKGROUND

Machine and equipment assets are engineered to perform particular tasks as part of a process. For example, assets can include, among other things and without limitation, industrial manufacturing equipment on a production line, drilling equipment for use in mining operations, wind turbines that generate electricity on a wind farm, transportation vehicles, gas and oil refining equipment, and the like. As another example, assets may include devices that aid in diagnosing patients such as imaging devices (e.g., X-ray or MM systems), monitoring equipment, and the like. The design and implementation of these assets often takes into account both the physics of the task at hand, as well as the environment in which such assets are configured to operate.

Low-level software and hardware-based controllers have long been used to drive machine and equipment assets. However, the rise of inexpensive cloud computing, increasing sensor capabilities, and decreasing sensor costs, as well as the proliferation of mobile technologies, have created opportunities for creating novel industrial and healthcare based assets with improved sensing technology and which are capable of transmitting data that can then be distributed throughout a network. As a consequence, there are new opportunities to enhance the business value of some assets through the use of novel industrial-focused hardware and software.

Software applications and other programs are often used as part of a process for enhancing or otherwise improving an operation of an asset. For example, software can be used to evaluate power consumption of the asset, evaluate operating speed, evaluate life of the asset, and the like. Based on various factors the software can suggest or otherwise modify the performance of an asset with one or more overall goals in mind. For example, if increasing the life of the asset is the priority, then the software may determine that decreasing operating speed (producing less) may be beneficial in the long run because such reduced operating speed will salvage additional life of the asset and ultimately lead to improved cost performance even though in the short term the output of the asset is reduced.

However, different customers have different operating environments for assets and software related thereto. Also, different customers have different objectives and reasons for downloading and installing software. As a result, an improvement in the operation of an asset as a result of downloading and installing an application for the asset may be different for different customers having different needs. Factors that can influence the level of improvement include other software installed, hardware component installed, the state of the hardware, the types of activities being performed by the asset, goals of the customer, and the like. Accordingly, what is needed is way of determining or otherwise proving the benefit of an asset-related application being installed for a respective customer and not customers in general.

### SUMMARY

According to an aspect of an example embodiment, a method may include one or more of determining an operating performance of an asset which is operating based on a performance modifying application being installed, establishing a baseline operating performance of the asset from a virtual model of the asset which is running without the performance modifying application being installed, determining a change in an operating characteristic of the asset in response to the performance modifying application being installed based on the operating performance of the asset which is determined from the asset and the baseline operating performance of the asset which is determined from the virtual model of the asset, and outputting information about the determined change in the operating characteristic of the asset for display on a display device.

According to an aspect of another example embodiment, a computing system may include one or more of a processor that may determine an operating performance of an asset which is operating based on a performance modifying application being installed, establish a baseline operating performance of the asset from a virtual model of the asset which is running without the performance modifying application being installed, and determine a change in an operating characteristic of the asset in response to the performance modifying application being installed based on the operating performance of the asset which is determined from the asset and the baseline operating performance of the asset which is determined from the virtual model of the asset, and an output that may output information about the determined change in the operating characteristic of the asset for display on a display device.

Other features and aspects may be apparent from the following detailed description taken in conjunction with the drawings and the claims.

### BRIEF DESCRIPTION OF THE DRAWINGS

Features and advantages of the example embodiments, and the manner in which the same are accomplished, will become more readily apparent with reference to the following detailed description taken in conjunction with the accompanying drawings.

FIG. 1 is a diagram illustrating a cloud computing system for industrial software and hardware in accordance with an example embodiment.

FIG. 2 is a diagram illustrating a system for instantiating a virtual asset in accordance with an example embodiment.

FIG. 3 is a diagram illustrating a process for determining a change in an operating characteristic of an asset due to a performance modifying application being installed in accordance with example embodiments.

FIG. 4 is a diagram illustrating a method for determining a change in an operating characteristic of an asset in accordance with an example embodiment.

FIG. 5 is a diagram illustrating a computing system for determining a change in an operating characteristic of an asset in accordance with an example embodiment.

Throughout the drawings and the detailed description, unless otherwise described, the same drawing reference numerals will be understood to refer to the same elements, features, and structures. The relative size and depiction of these elements may be exaggerated or adjusted for clarity, illustration, and/or convenience.

### DETAILED DESCRIPTION

In the following description, specific details are set forth in order to provide a thorough understanding of the various example embodiments. It should be appreciated that various modifications to the embodiments will be readily apparent to those skilled in the art, and the generic principles defined herein may be applied to other embodiments and applications without departing from the spirit and scope of the disclosure. Moreover, in the following description, numerous details are set forth for the purpose of explanation. However, one of ordinary skill in the art should understand that embodiments may be practiced without the use of these specific details. In other instances, well-known structures and processes are not shown or described in order not to obscure the description with unnecessary detail. Thus, the present disclosure is not intended to be limited to the embodiments shown, but is to be accorded the widest scope consistent with the principles and features disclosed herein.

The example embodiments are directed to a system and method for determining the effect of a software application on a physical asset by launching and monitoring an unoptimized digital twin of the asset. Software applications may be downloaded and installed on a physical asset (e.g., machine or equipment) or in association with the physical asset (e.g., on a control system, cloud, gateway, industrial pc, etc.) and used to optimize or otherwise enhance a performance or an operation of the asset. The asset may be a structural (hardware) based asset. As another example, the asset may be a software process. For example, a power plant may have a distributed control system which controls behavior across the plant and a software application may be used to enhance the behavior of the control system or constrain the system. The asset in this case may be the software application which enhances the control system.

The optimization software may be used by an asset or a control system of the asset to add life to the asset or its components by changing speeds, power levels, operating conditions, bandwidth consumption, and the like. As another example, optimization applications may be used to improve a level of manufacturing output (e.g., speed, amount, quality, etc.) by the asset, a quality of the manufacturing of the asset, and the like. The system herein generates a mirror of input data from the physical asset and applies it as an input to the digital twin (i.e., virtual model) which virtually represents an unoptimized (i.e., without the optimization application) version of the physical asset. The digital twin provides a mechanism for establishing baseline operating performance using actual data that is more robust and dynamic than using prior data, resulting in a better estimation of the amount of improvement offered to the asset as a result of the application.

The system can determine an actual operating performance of the asset after a software application has been installed by monitoring operating characteristics and data received from the asset. In addition, the system can instantiate and execute a digital twin of the asset without the software being installed and virtually determine a baseline operating performance of the virtual asset by monitoring operating characteristics and data received from the virtual asset. The system can mirror the input data that is going into the actual asset and input the same input data to the virtual asset. The system can also determine a change in an operating characteristic (e.g., component life, power consumption, speed, quality, etc.) of the asset based on the operating performance from the actual asset with the software installed in comparison with the virtual operating performance of the virtual asset without the software installed. Additional functions may be performed based on the determined change such as installation of additional optimization programs or hardware, cost evaluation determinations for purchasing or charging for use of the software, and the like.

The system may be implemented via a program or other software that may be used in conjunction with applications for managing machine and equipment assets hosted within an Industrial Internet of Things (IIoT). An IIoT may connect assets, such as turbines, jet engines, locomotives, elevators, healthcare devices, mining equipment, oil and gas refineries, and the like, to the Internet or cloud, or to each other in some meaningful way such as through one or more networks. The software program described herein can be implemented within an application marketplace or application store deployed in a “cloud” or remote or distributed computing resource. The cloud can be used to receive, relay, transmit, store, analyze, or otherwise process information for or about assets and manufacturing sites. In an example, a cloud computing system includes at least one processor circuit, at least one database, and a plurality of users or assets that are in data communication with the cloud computing system. The cloud computing system can further include or can be coupled with one or more other processor circuits or modules configured to perform a specific task, such as to perform tasks related to asset maintenance, analytics, data storage, security, or some other function.

An application marketplace refers to a digital distribution platform for software. An application marketplace may organize the apps that it offers based on various factors including functions provided by the app (e.g., games, multimedia, productivity, etc.), a device for which the app was designed, an operating system on which the app will run, and the like. The application marketplace may take the form of an online store, where users can browse through different applications and categories, view information about each app (such as reviews or ratings), and acquire the application. A selected application may be offered as an automatic download, after which the application installs in the target download environment.

An application marketplace may include different software applications published by distinct software developers. The application marketplace may receive a uniform resource locator (URL) of an application used to launch the application, screen shots, one or more icons, a manifest file, and the like, from the developer of the application desiring to publish the application through the application marketplace. After the application is submitted, it is often reviewed to ensure various requirements (e.g., security, operation, etc.) and when approved it is made available via the application marketplace.

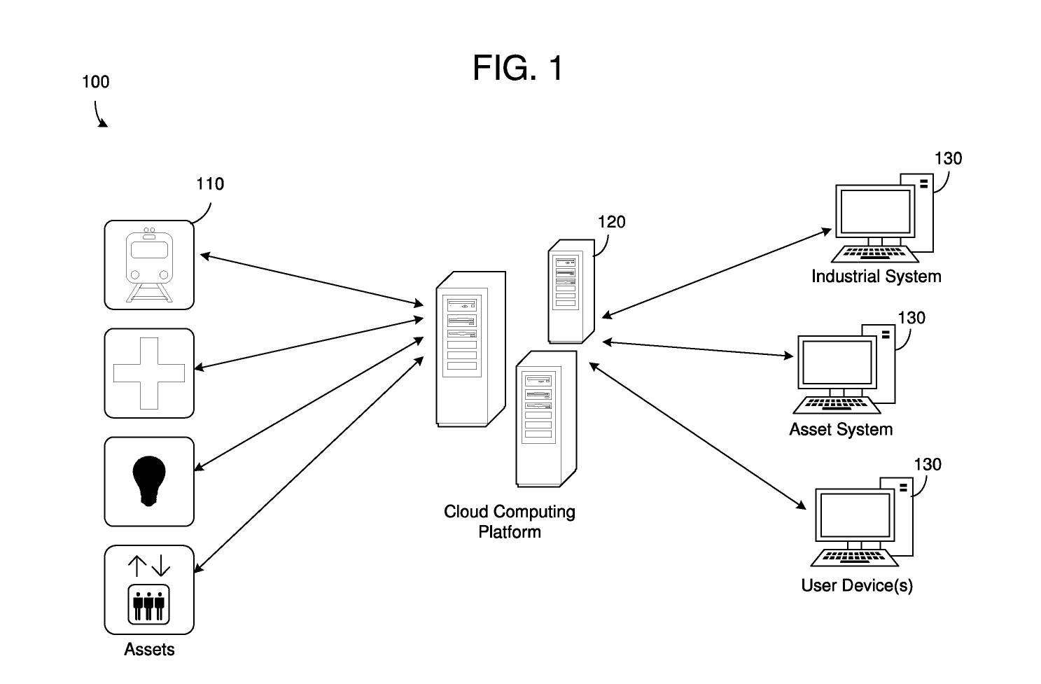

FIG. 1 illustrates a cloud computing system 100 for industrial software and hardware in accordance with an example embodiment. Referring to FIG. 1, the system 100 includes a plurality of assets 110 which may be included within an Industrial Internet of Things (IIoT) and which may transmit raw data to a source such as cloud computing platform 120 where it may be stored and processed. It should also be appreciated that the cloud platform 120 in FIG. 1 may not be a cloud storage but may be a non-cloud based platform such as a server, an on-premises computing system, and the like. The data transmitted by the assets 110 and received by the cloud platform 120 may include data that is being input to hardware and/or software deployed on or in association with the assets 110, raw time-series data output as a result of the operation of the assets 110, and the like.

Data that is stored and processed by the cloud platform 120 may be output in some meaningful way to industrial computing systems 130. In the example of FIG. 1, the assets 110, cloud platform 120, and industrial computing systems 130 may be connected to each other via a network such as the Internet, a private network, a wired network, a wireless network, etc. The industrial computing systems 130 may include industrial personal computers, gateways, asset-related systems, user devices (workstations, desktops, tablets, mobile phones, etc.), and the like. The industrial computing systems 130 may interact with software hosted by and deployed on the cloud platform 120 in order to receive data from and control operation of the assets 110.

According to various aspects, software applications that can be used to enhance or otherwise modify the operating performance of an asset 110 may be hosted by the cloud platform 120 and may operate on the asset 110 and/or one or more of the industrial computing systems 130. For example, software applications may be used to optimize a performance of the assets 110 or data coming in from the asset 110. As another example, the software applications may analyze, control, manage, or otherwise interact with the asset 110 and components (software and hardware) thereof. An industrial computing system 130 may receive views of data or other information about the asset 110 as the data is processed via one or more applications hosted by the cloud platform 120. For example, the industrial computing system 130 may receive graph-based results, diagrams, charts, warnings, measurements, power levels, and the like. As another example, the industrial computing system 130 may display a graphical user interface that allows a user thereof to input commands to an asset 110 via one or more applications hosted by the cloud platform 120.

In this example, an asset management platform (AMP) can reside within or be connected to the cloud platform 120, in a local or sandboxed environment, or can be distributed across multiple locations or devices and can be used to interact with the assets 110. The AMP can be configured to perform functions such as data acquisition, data analysis, data exchange, and the like, with local or remote assets 110, or with other task-specific processing devices. For example, the assets 110 may be an asset community (e.g., turbines, healthcare, power, industrial, manufacturing, mining, oil and gas, elevator, etc.) which may be communicatively coupled to the cloud platform 120 via one or more intermediate devices such as a stream data transfer platform, database, or the like.

Information from the assets 110 may be communicated to the cloud platform 120. For example, external sensors can be used to sense information about a function of an asset, or to sense information about an environment condition at or around an asset, a worker, a downtime, a machine or equipment maintenance, and the like. The external sensor can be configured for data communication with the cloud platform 120 which can be configured to store the raw sensor information and transfer the raw sensor information to the industrial computing systems 130 where it can be accessed by users, applications, systems, and the like, for further processing. Furthermore, an operation of the assets 110 may be enhanced or otherwise controlled by a user inputting commands though an application hosted by the cloud platform 120 or other remote host platform such as a web server. The data provided from the assets 110 may include time-series data or other types of data associated with the operations being performed by the assets 110

In some embodiments, the cloud platform 120 may include a local, system, enterprise, or global computing infrastructure that can be optimized for industrial data workloads, secure data communication, and compliance with regulatory requirements. The cloud platform 120 may include a database management system (DBMS) for creating, monitoring, and controlling access to data in a database coupled to or included within the cloud platform 120. The cloud platform 120 can also include services that developers can use to build or test industrial or manufacturing-based applications and services to implement IIoT applications that interact with assets 110. For example, the cloud platform 120 may host an industrial application marketplace where developers can publish their distinctly developed applications and/or retrieve applications from third parties. In addition, the cloud platform 120 can host a development framework for communicating with various available services or modules. The development framework can offer developers a consistent contextual user experience in web or mobile applications. Developers can add and make accessible their applications (services, data, analytics, etc.) via the cloud platform 120. Also, analytic software may analyze data from or about a manufacturing process and provide insight, predictions, and early warning fault detection.

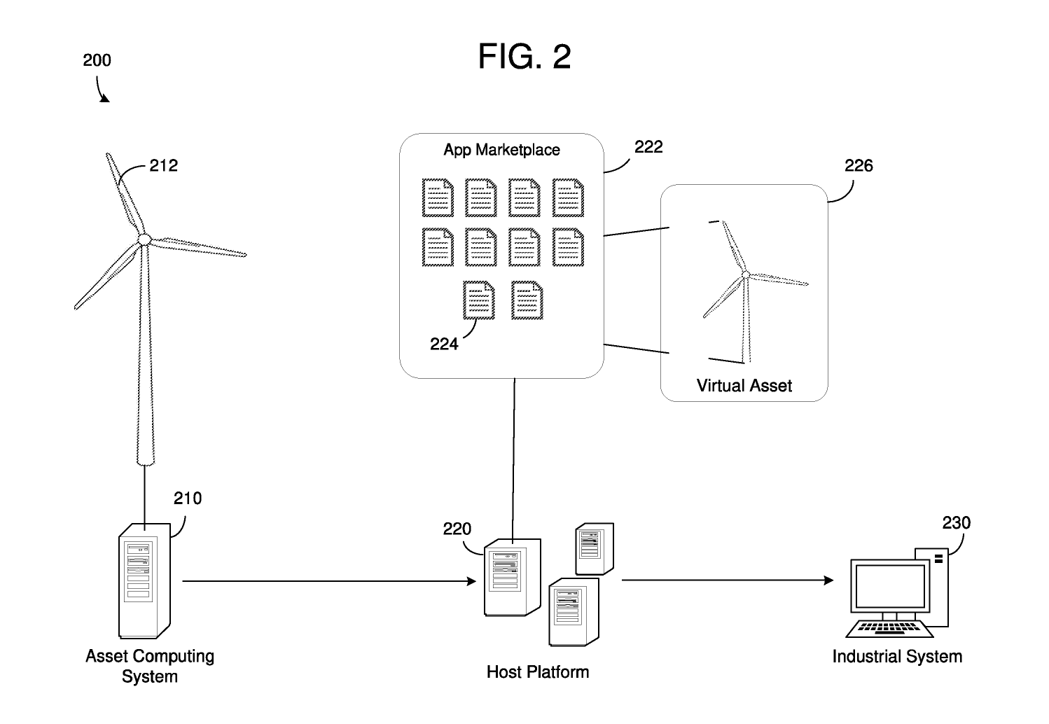

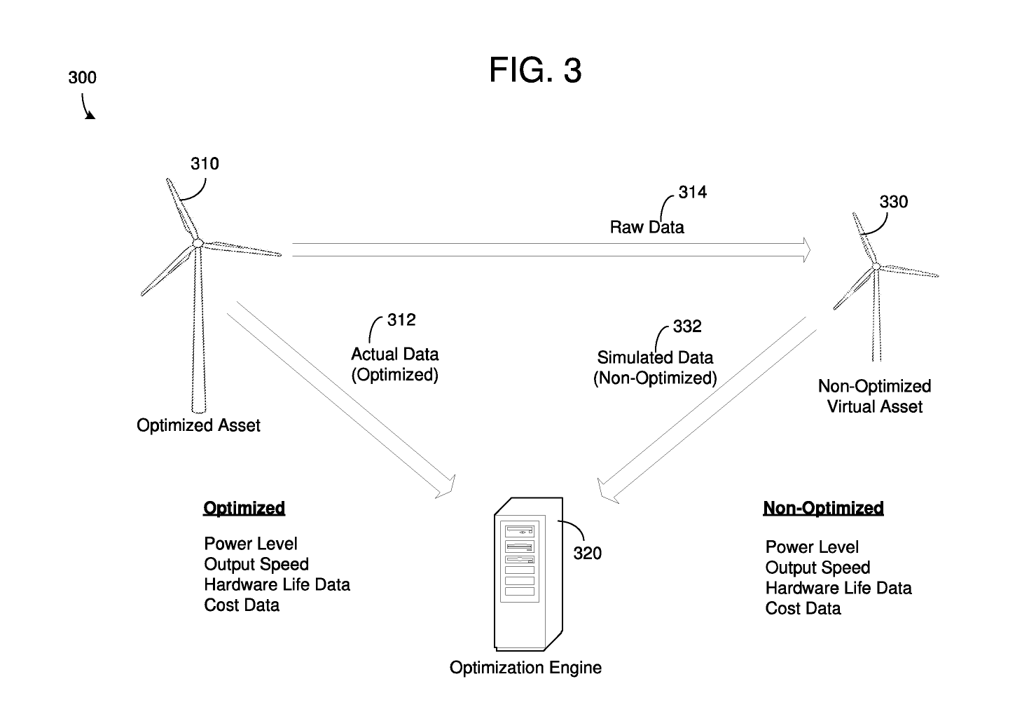

FIG. 2 illustrates a system 200 for instantiating a virtual asset in accordance with an example embodiment, and FIG. 3 illustrates a process 300 for determining a change in an operating characteristic of an asset due to a performance modifying application being installed on the asset or in association with the asset in accordance with example embodiments. Both the system 200 of FIG. 2 and the process 300 of FIG. 3 may be performed by the system 100 shown in FIG. 1. It should also be appreciated that another system may be used and various features may be omitted such as the cloud platform, one or more assets, or the like. Referring to FIG. 2, the system 200 includes an asset 212 that is coupled to an asset computing system 210 which feeds data about the asset 212 to the host platform 220. It should also be understood that the asset 212 may transmit data directly to host platform 220 without the use of asset computing system 210.

In some embodiments, the host platform 220 may host an application marketplace 222 which publishes and makes accessible industrial-based applications 224 for download and install by users such as industrial computing system 230 which may be a gateway, an industrial edge computer, an asset-coupled computer, a user device, and the like. In some embodiments, the applications 224 may be used to optimize or otherwise modify an operating performance of the asset 212. For example, applications 224 may be used to improve profitability of the asset 212 by managing or otherwise controlling one or more of processing speed, power consumption, data output, quality, and the like, of the asset. Also, the applications 224 may be used to control a life of the asset 212 or one or more components of the asset 212. Here, the performance modifying application 224 may be installed by or in association with a control system of the asset 212.

The amount of enhancement or improvement of the asset 212 as a result of the application 224 being installed (e.g., by a control system) may be determined by a software program described herein. For example, the software program may include an optimization engine executing on the host platform 220 and associated with or even controlled by the application marketplace 222. The software may determine an amount of change to an operating characteristic of the asset 212 by determining an amount of power conserved by the asset 212 over a period of time, an amount of data or product output of the asset 212 over a period of time, a quality of the product or data output by the asset 212 over time, and the like, which are generated by the installation of the performance modifying software on the asset 212 or the asset control system. As another example, the change to the asset 212 may be determined by how much life is added to the asset 212 as a result of the application being installed which may be predicted by the optimization engine (e.g., optimization engine 320 in FIG. 3).

According to various aspects, in order to evaluate and determine the change of the asset 212 as a result of the application 224 being installed, the host platform 220 may launch a digital twin 226 (i.e., virtual model) of the asset 212. The digital twin 226 may be a virtualized twin also referred to as a virtual asset which is a virtual model having a same size and components of the actual asset 212 but which are implemented in virtual space. That is, the digital twin 226 may be a virtual replica (e.g., size, shape, inputs, environment, surrounding machines and equipment, etc.) of the actual asset 212. Although not shown in FIG. 2, as another example, the asset 212 may be a software asset such as a process or method of manufacture involving software which may also include a digital twin.

The digital twin 226 may be a standard virtual replica of the asset 212. As another example, the digital twin 226 may be implemented with one or more machine learning models trained from data from the same asset, one or more machine learning model trained from similar assets, one or more physics based models or system of physics based models that to model the physical characteristics of the asset, one or more hybrid models that incorporate both machine learning and physics based models, and the like. A catalog or pool of digital twins may be stored by the host platform 220. The host platform 220 may programmatically select and launch a digital twin from the catalogue based on characteristics of the asset being optimized, analytics that might apply, and the like. For example, the host platform 220 may automatically select and launch a digital twin implemented with a different analytic based on whether the asset is being optimized for maximum power output versus being optimized for maximum efficiency. That is, the host platform 220 may programmatically select an appropriate digital twin based on the characteristics of the asset being optimized/modeled or the optimization being provided by the selected application.

According to various embodiments, the host platform 220 may instantiate the digital twin 226 without the application 224 being installed in association with the digital twin 226 to establish a baseline operating performance of the asset 212. For example, the digital twin 226 may be instantiated and executed based on a request from the industrial computing system 230, automatically in response to an application 224 being downloaded and installed from the application marketplace 222, or the like. Here, the digital twin 226 may execute in a virtual environment created by the host platform 220 and can transmit information about the virtual execution of the digital twin 226 to one or more applications hosted by the host platform 220. According to various aspects, the host platform 220 can monitor the input data which is being fed into the asset 212 and mirror that data as input into the digital twin 226. Furthermore, the host platform 220 can monitor the performance of the digital twin 226. That is, one or more software programs hosted by the host platform 220 may monitor an operating performance of both the asset 212 and the digital twin 226. Here, the digital twin 226 may be launched simultaneously with the operation of the asset 212 or it may be launched sequentially.

In this example, the host platform 220 may include software which can determine an improvement to an operating characteristic of the asset 212 as a result of the application 224 being installed by comparing the operation of the asset 212 with the operation of the digital twin 226 which does not have the application 224 installed. The determination may be based on an amount of power conserved, a change in quality of data provided by the asset (e.g., less error, etc.), an change in output speed of manufacturing, etc., an improvement in a life of the asset 212, or the like. Information about the change may be output for display on a screen associated with the industrial computing system 230. Also, additional actions can be performed based on the determined amount of change. In some embodiments, an amount at which the host platform 220 charges a user of the industrial computing system 230 for the application 224 can be dictated by the amount of improvement that is determined to be generated by the application 224. As another example, information about additional modifications that can be made to asset 212 as a result of the level of improvement can be provided to the industrial computing device 230.

As shown in FIG. 3, an optimized asset 310 is operating based on a performance modifying software that has been installed, for example, on the asset 310 or in a computing system associated with the asset 310. Meanwhile non-optimized virtual asset 330 is operating without the performance modifying software being installed. Here, the non-optimized virtual asset 330 generates and transmits simulated data 332 to the optimization engine 320 while the optimized asset 310 generates and transmits actual data 312 to the optimization engine. The data (e.g., actual 312 and simulated 332) may be used to determine an operating performance of both the asset 310 and the non-optimized virtual asset 330. Furthermore, the optimization engine 320 may compare the operating performances of the optimized asset 310 and the non-optimized virtual asset 330 to determine a change or an amount of improvement in an operating characteristic of the optimized asset 310 due to the performance modifying software being installed.

The optimization engine 320 may include systems and software that can increase profitability by means of optimization methods. The optimization engine 320 may evaluate an operating performance (e.g., power consumption, waste, raw material consumption, output speed, hardware life, cost, etc.) of the asset 310 or one or more components of asset 310 based on the actual data 312 and determine how to maximize profitability of the asset 310. The optimization engine 320 may also evaluate an operating performance of the virtual asset 330 based on the simulated data 332 received. The optimization engine 320 may also detect changes to the asset 310 or a component of the asset 310 as a result of the installation of the performance modifying software on the asset 310 using a baseline operating performance established using the virtual asset 320 and predict how these changes have improved the overall life of the asset 310. In some cases, it may be more cost beneficial to improve the life of the asset 310 even at an expense of less production, less output speed, or greater power consumption. As another example, the optimization engine 320 may predict how these changes have improved processing speed, power consumption, quality, raw material consumption, or the like.

In some embodiments, the asset 310 may also transmit/pipe real-time sensor data (i.e., raw data sensed from the asset) to the virtual asset 330. As another example, the raw sensor data may be transmitted from the optimization engine 320 to the virtual asset 330 in an example in which the optimization engine 320 receives both optimized data and raw data from the asset 310. Accordingly, the virtual asset 330 may simulate/operate based on actual data being streamed from the asset 310 to provide accurate results. In this example, the optimization engine 320 and/or the asset 310 may automatically establish an appropriate communication interface/channel between the optimization engine 320 and/or the asset 310 for streaming the raw data 314 from the asset 310 to the virtual asset 330. For example, of the optimization engine 320 may include a management component on the optimization engine 320 that is capable of receiving a data stream from the asset 310 and piping it to an address for the virtual asset 330 based on instructions received from the application marketplace at the time the application is installed and/or at the time the virtual asset 330 is instantiated.

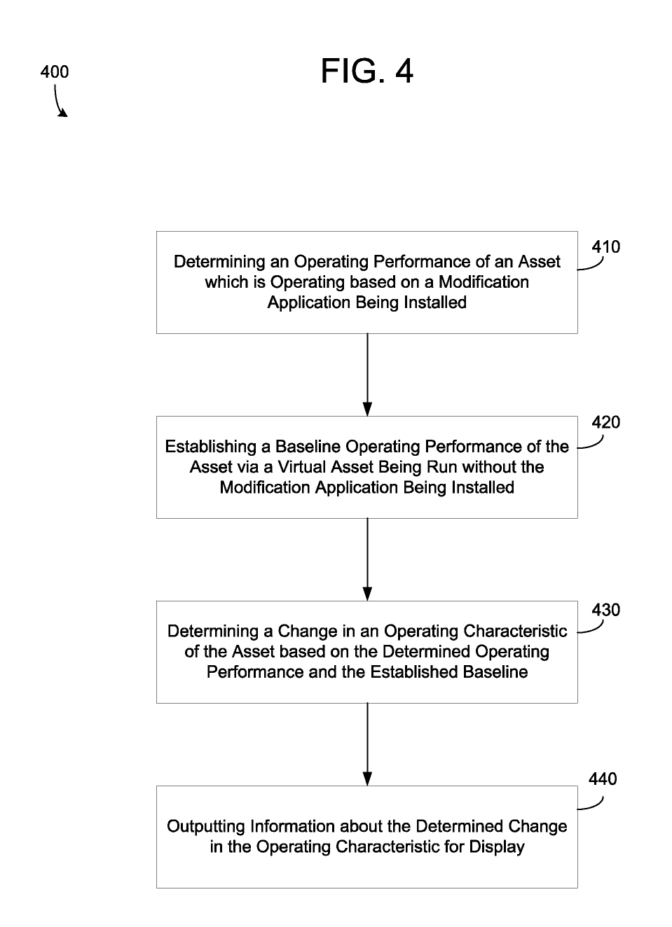

FIG. 4 illustrates a method 400 for determining a change in an operating characteristic of an asset in accordance with an example embodiment. For example, the method 400 may be performed by a server, a cloud computing platform, a database, a computing system, a user device, and the like. Referring to FIG. 4, in 410, the method includes determining an operating performance of an asset which is operating based on a performance modifying application being installed. For example, the asset may include a machine or an equipment used in manufacturing, healthcare, industry, energy, and transportation. and the like. The performance may include monitoring one or more operating characteristics of the asset over time such as power consumption, output speed, quality, degradation of hardware or software, and the like. In some embodiments, the operating performance may include life information about a physical component of the asset which can be determined based on wear and tear on the asset. The life information may be generated by an optimization engine which can determine how much life the asset has left before needing to be replaced or how much life has been lost by the asset over time.

In 420, the method includes establishing a baseline operating performance of the asset from a virtual model of the asset which is running without the performance modifying application being installed. For example, the baseline operating performance of the asset may be measured by inputting data inputs to the virtual model that are equivalent to or otherwise mirror the inputs of the actual asset. In some cases, the virtual asset may be running at the same time the actual asset is operating. As another example, the virtual asset may be executed before or after the actual asset begins operating. In some embodiments, the method may also include instantiating and executing the virtual model of the asset without the performance modifying application installed in response to receiving a request from a user of the asset. For example, the request may be received via a user interface associated with the asset or associated, an application marketplace where the application is downloaded from, and the like. In some embodiments, the virtual model of the asset may be instantiated by the application marketplace.

In 430, the method includes determining a change in an operating characteristic of the asset in response to the performance modifying application being installed based on the operating performance of the asset and the baseline operating performance of the asset which is determined from the virtual model of the asset. The change in the operating characteristic of the asset may include an amount of life that has been gained by the addition of the software application, an amount of cost saved as a result of the asset, an amount of power conserved, an amount of output that has been increased, a measure of quality increase (e.g., percentage of error), and the like. In 440, the method includes outputting information about the determined change in the operating characteristic of the asset for display on a display device. Although not shown in FIG. 4, the method may also include performing additional determinations based on the change in the operating characteristic. For example, additional software and hardware optimizations can be suggested, cost calculations can be performed to determine how much to charge the user of the application, and the like.

In some embodiments, the determining of the operating performance of the asset in 410 may include determining one or more of a loss of life of the asset over time, a power consumption of the asset over time, and an output speed of the asset over time, and the establishing of the baseline operating performance of the asset comprises determining one or more of a loss of life of the virtual model over time, a power consumption of the virtual model over time, and an output speed of the virtual model over time, in 420. In this example, the determining of the change in the operating characteristic of the asset in 430 may include determining an increase in an amount of life of the asset in response to the performance modifying application being installed, determining one or more of an increase in processing speed and a reduction in power consumption of the asset in response to the performance modifying application being installed, and the like.

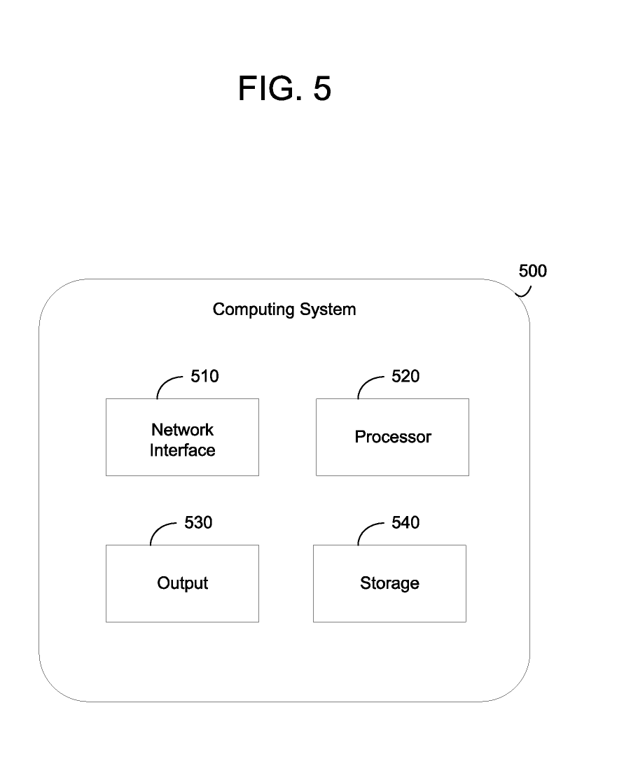

FIG. 5 illustrates a computing system for determining a change in an operating characteristic of an asset in accordance with an example embodiment. For example, the computing system 500 may be a database, cloud platform, streaming platform, user device, and the like. As a non-limiting example, the computing system 500 may be the cloud platform 120 shown in FIG. 1. In some embodiments, the computing system 500 may be distributed across multiple devices. Also, the computing system 500 may perform the method 400 of FIG. 4. Referring to FIG. 5, the computing system 500 includes a network interface 510, a processor 520, an output 530, and a storage device 540 such as a memory. Although not shown in FIG. 5, the computing system 500 may include other components such as a display, an input unit, a receiver, a transmitter, and the like.

The network interface 510 may transmit and receive data over a network such as the Internet, a private network, a public network, and the like. The network interface 510 may be a wireless interface, a wired interface, or a combination thereof. The processor 520 may include one or more processing devices each including one or more processing cores. In some examples, the processor 520 is a multicore processor or a plurality of multicore processors. Also, the processor 520 may be fixed or it may be reconfigurable. The output 530 may output data to an embedded display of the computing system 500, an externally connected display, a display connected to the cloud, another device, and the like. The storage device 540 is not limited to a particular storage device and may include any known memory device such as RAM, ROM, hard disk, and the like, and may or may not be included within the cloud environment. The storage 540 may store software modules or other instructions which can be executed by the processor 520 to perform the method 400 shown in FIG. 4.

According to various embodiments, the processor 520 may determine an operating performance of an asset which is operating based on a performance modifying application being installed. The processor 520 may further establish a baseline operating performance of the asset by instantiating a virtual model of the asset which is running without the performance modifying application being installed. In some embodiments, the processor 520 may instantiate the virtual model of the asset via an application marketplace which makes the performance modifying application accessible to end users. In some embodiments, the processor 520 may establish the baseline operating performance of the asset by generating inputs for the virtual model that are equivalent to inputs of the asset.

The processor 520 may further determine a change in an operating characteristic of the asset in response to the performance modifying application being installed. The processor 520 may determine the change in the operating characteristic based on the operating performance of the asset which is determined from the asset and the baseline operating performance of the asset which is determined from the virtual model of the asset. For example, the performance of the asset and the performance of the virtual machine may be monitored by an optimization engine which is executed by the processor 520 and stored in the storage 540. The optimization engine make various determinations based on the monitoring of both the actual asset and the virtual asset. For example, the optimization engine may determine an amount of life that is conserved by adding the software application to the asset. The optimization engine can also determine how much processing power is conserved. The optimization engine can also determine a level of profitability of the asset. Furthermore, the output 530 may output information about the determined change in the operating characteristic of the asset for display on a display device.

In some embodiments, the processor is configured to determine the operating performance of the asset by determining one or more of a loss of life of the asset over time, a power consumption of the asset over time, and an output speed of the asset over time, and the establish the baseline operating performance of the asset by determining one or more of a loss of life of the virtual model over time, a power consumption of the virtual model over time, and an output speed of the virtual model over time. Here, the processor 520 may determine the change in the operating characteristic of the asset by determining an increase in an amount of life of the asset in response to the performance modifying application being installed. As another example, the processor 520 may determine the change in the operating characteristic of the asset by determining one or more of an increase in processing speed and a reduction in power consumption of the asset in response to the performance modifying application being installed.

As will be appreciated based on the foregoing specification, the above-described examples of the disclosure may be implemented using computer programming or engineering techniques including computer software, firmware, hardware or any combination or subset thereof. Any such resulting program, having computer-readable code, may be embodied or provided within one or more non-transitory computer readable media, thereby making a computer program product, i.e., an article of manufacture, according to the discussed examples of the disclosure. For example, the non-transitory computer-readable media may be, but is not limited to, a fixed drive, diskette, optical disk, magnetic tape, flash memory, semiconductor memory such as read-only memory (ROM), and/or any transmitting/receiving medium such as the Internet, cloud storage, the internet of things, or other communication network or link. The article of manufacture containing the computer code may be made and/or used by executing the code directly from one medium, by copying the code from one medium to another medium, or by transmitting the code over a network.

The computer programs (also referred to as programs, software, software applications, “apps”, or code) may include machine instructions for a programmable processor, and may be implemented in a high-level procedural and/or object-oriented programming language, and/or in assembly/machine language. As used herein, the terms “machine-readable medium” and “computer-readable medium” refer to any computer program product, apparatus, cloud storage, internet of things, and/or device (e.g., magnetic discs, optical disks, memory, programmable logic devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal that may be used to provide machine instructions and/or any other kind of data to a programmable processor.

The above descriptions and illustrations of processes herein should not be considered to imply a fixed order for performing the process steps. Rather, the process steps may be performed in any order that is practicable, including simultaneous performance of at least some steps. Although the disclosure has been described in connection with specific examples, it should be understood that various changes, substitutions, and alterations apparent to those skilled in the art can be made to the disclosed embodiments without departing from the spirit and scope of the disclosure as set forth in the appended claims.

What is claimed is:

1. A computer-implemented method comprising:
determining an operating performance of an asset which is operating based on a performance modifying application being installed;
establishing a baseline operating performance of the asset from a virtual model of the asset which is running without the performance modifying application being installed;
determining a change in an operating characteristic of the asset in response to the performance modifying application being installed based on the operating performance of the asset which is determined from the asset and the baseline operating performance of the asset which is determined from the virtual model of the asset; and
outputting information about the determined change in the operating characteristic of the asset for display on a display device.

2. The computer-implemented method of claim 1, further comprising instantiating and executing the virtual model of the asset without the performance modifying application installed in response to receiving a request from a user of the asset.

3. The computer-implemented method of claim 2, wherein the virtual model of the asset is instantiated by an application marketplace which makes the performance modifying application accessible to end users.

4. The computer-implemented method of claim 1, wherein the asset comprises at least one of a machine or equipment used in a field of at least one of manufacturing, healthcare, industry, energy, and transportation.

5. The computer-implemented method of claim 1, wherein the establishing the baseline operating performance of the asset comprises generating inputs for the virtual model that are equivalent to inputs of the asset.

6. The computer-implemented method of claim 1, further comprising automatically selecting the virtual model from among a plurality of virtual models based on the performance modifying application.

7. The computer-implemented method of claim 6, wherein the virtual model is selected from among the plurality of virtual models based on a function of the asset to be modified by the performance modifying application.

8. The computer-implemented method of claim 1, wherein the determining of the operating performance of the asset comprises determining one or more of a loss of life of the asset over time, a power consumption of the asset over time, and an output of the asset over time, and the establishing of the baseline operating performance of the asset comprises determining one or more of a loss of life of the virtual model over time, a power consumption of the virtual model over time, and an output of the virtual model over time.

9. The computer-implemented method of claim 8, wherein the determining of the change in the operating characteristic of the asset comprises determining an increase in an amount of life of the asset in response to the performance modifying application being installed.

10. The computer-implemented method of claim 8, wherein the determining of the change in the operating characteristic of the asset comprises determining one or more of an increase in processing speed and a reduction in power consumption of the asset in response to the performance modifying application being installed.

11. A computing system comprising:
a processor configured to determine an operating performance of an asset which is operating based on a performance modifying application being installed, establish a baseline operating performance of the asset from a virtual model of the asset which is running without the performance modifying application being installed, and determine a change in an operating characteristic of the asset in response to the performance modifying application being installed based on the operating performance of the asset which is determined from the asset and the baseline operating performance of the asset which is determined from the virtual model of the asset; and
an output configured to output information about the determined change in the operating characteristic of the asset for display on a display device.

12. The computing system of claim 11, wherein the processor is further configured to instantiate and execute the virtual model of the asset without the performance modifying application installed in response to receiving a request from a user of the asset.

13. The computing system of claim 12, wherein the processor instantiates the virtual model of the asset via an application marketplace which makes the performance modifying application accessible to end users.

14. The computing system of claim 11, wherein the asset comprises at least one of a machine or equipment used in a field of at least one of manufacturing, healthcare, industry, energy, and transportation.

15. The computing system of claim 11, wherein the processor is configured to establish the baseline operating performance of the asset by generating inputs for the virtual model that are equivalent to inputs of the asset.

16. The computing system of claim 11, wherein the processor is configured to determine the operating performance of the asset by determining one or more of a loss of life of the asset over time, a power consumption of the asset over time, and an output of the asset over time, and the establish the baseline operating performance of the asset by determining one or more of a loss of life of the virtual model over time, a power consumption of the virtual model over time, and an output of the virtual model over time.

17. The computing system of claim 16, wherein the processor is configured to determine the change in the operating characteristic of the asset by determining an increase in an amount of life of the asset in response to the performance modifying application being installed.

18. The computing system of claim 16, wherein the processor is configured to determine the change in the operating characteristic of the asset by determining one or more of an increase in processing speed and a reduction in power consumption of the asset in response to the performance modifying application being installed.

19. A non-transitory computer readable medium having stored therein instructions that when executed cause a computer to perform a method comprising:
determining an operating performance of an asset which is operating based on a performance modifying application being installed;
establishing a baseline operating performance of the asset from a virtual model of the asset which is running without the performance modifying application being installed;
determining a change in an operating characteristic of the asset in response to the performance modifying application being installed based on the operating performance of the asset which is determined from the asset and the baseline operating performance of the asset which is determined from the virtual model of the asset; and
outputting information about the determined change in the operating characteristic of the asset for display on a display device.

20. The non-transitory computer readable medium of claim 19, wherein the method further comprises instantiating and executing the virtual model of the asset without the performance modifying application installed in response to receiving a request from a user of the asset.
